(19) United States
(12) Patent Application Publication
(10) Pub. No.: US 2026/0076217 A1
(43) Pub. Date: Mar. 12, 2026

(54) SEMICONDUCTOR PACKAGE SUBSTRATE INCLUDING GRAPHENE LAYER, METHOD OF MANUFACTURING THE SEMICONDUCTOR PACKAGE SUBSTRATE, AND SEMICONDUCTOR PACKAGE INCLUDING THE SEMICONDUCTOR PACKAGE SUBSTRATE

(71) Applicant: HAESUNG DS CO., LTD., Gyeongsangnam-do (KR)

(72) Inventors: Min PARK, Gyeongsangnam-do (KR); Su Yeon SON, Gyeongsangnam-do (KR); Ho Sang YU, Gyeongsangnam-do (KR); Jin Woo LEE, Gyeongsangnam-do (KR); Hyun Ji YUN, Gyeongsangnam-do (KR)

(21) Appl. No.: 19/240,074

(22) Filed: Jun. 17, 2025

(30) Foreign Application Priority Data
Jun. 18, 2024 (KR) 10-2024-0078988

(51) Int. Cl. H01L 23/495; H01L 21/48; H01L 23/00; H01L 23/31

(52) U.S. Cl. CPC H10W 70/457; H10W 74/114; H10W 70/04; H10W 70/417; H10W 72/884; H10W 90/736; H10W 90/756

(57) ABSTRACT

A semiconductor package substrate includes a base substrate including a conductive material, a die pad portion, and a lead portion, a metal catalyst layer disposed on the base substrate, and a graphene layer disposed on the metal catalyst layer, wherein the semiconductor package substrate has a Vickers hardness of 135 to 150.

### CROSS-REFERENCE TO RELATED APPLICATION

This application is based on and claims priority under 35 U.S.C. § 119 to Korean Patent Application No. 10-2024-0078988, filed on Jun. 18, 2024, in the Korean Intellectual Property Office, the disclosure of which is incorporated by reference herein in its entirety.

### BACKGROUND

### 1. Field

The disclosure relates to a semiconductor package substrate including a graphene layer, a method of manufacturing the semiconductor package substrate, and a semiconductor package including the semiconductor package substrate.

### 2. Description of the Related Art

In general, semiconductor packages imply forming a signal withdrawal terminal on a main board by using a lead frame and molding the signal withdrawal terminal by using molding materials in order to protect a semiconductor chip such as a single element with various electronic circuits and wirings, an integrated circuit, or a hybrid circuit from various external environments such as dust, moisture, electrical and mechanical loads, and optimize and maximize the performance of the semiconductor chip. The lead frame refers to a material that simultaneously serves as a lead that connects an input/output pad of the semiconductor chip to the electrical circuit formed on the main board and as a support that fixes the semiconductor package to the main board.

Typically, semiconductor packages are formed by placing a semiconductor chip on a pad of the lead frame, wire bonding the electrode of the semiconductor chip and an inner lead of the lead frame, and then encapsulating the pad and the inner lead frame with a molding resin. According to recent trends, the capacity of semiconductor packages has been increased and sizes thereof have been reduced.

A semiconductor package board is an intermediate part that electrically connects a semiconductor chip to an external device such as a printed circuit board. The semiconductor package substrate may serve to support the semiconductor chip, and the semiconductor chip and the semiconductor package substrate may be electrically connected to each other through wire bonding or solder bumps.

Because the semiconductor package substrate mainly includes a copper metal, an oxide layer may be formed on the semiconductor package substrate by oxygen and water vapor in the air. In this case, wire bonding may not be possible or bonding strength may be lowered. In the related art, a method of plating an inert metal with low reactivity on the semiconductor package substrate or a method of coating an organic film on the semiconductor package substrate has been introduced to prevent the formation of such an oxide layer.

### SUMMARY

However, the method of plating inert metal is expensive when the entire plating is performed due to the high cost of the metal, and the process may be complicated when only a part where wire bonding is performed is plated.

In addition, the method of coating the organic film has a problem that the wire bonding or solder bump bonding process may not be performed smoothly because the organic film is coated in tens of micro thickness to obtain a sufficient anti-oxidation period.

Provided is a semiconductor package substrate including a graphene layer as an anti-oxidation film, a method of manufacturing the semiconductor package substrate, and a semiconductor package including the semiconductor package substrate. The semiconductor package substrate including the graphene layer may further improve the adhesion of a semiconductor chip in a process of manufacturing the semiconductor package by mounting the semiconductor chip. However, these solutions are exemplary, and the scope of the disclosure is not limited thereto.

Additional aspects will be set forth in part in the description which follows and, in part, will be apparent from the description, or may be learned by practice of the presented embodiments of the disclosure.

According to an aspect of the disclosure, a semiconductor package substrate includes a base substrate including a conductive material, a die pad portion, and a lead portion, a metal catalyst layer disposed on the base substrate, and a graphene layer disposed on the metal catalyst layer, wherein the semiconductor package substrate has a Vickers hardness of 135 to 150.

In an embodiment, the metal catalyst layer may include at least one of copper (Cu), nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt).

In an embodiment, the base substrate may include copper (Cu).

In an embodiment, the graphene layer may be directly disposed on the metal catalyst layer.

In an embodiment, no oxide layer may be disposed between the graphene layer and the metal catalyst layer.

In an embodiment, the metal catalyst layer may be disposed on at least one of a first surface of the base substrate, a second surface located on the opposite side of the first surface, and a third surface connecting the first surface to the second surface.

In an embodiment, the graphene layer may be disposed on at least one of a first surface of the metal catalyst layer, a second surface located on the opposite side of the first surface, and a third surface connecting the first surface to the second surface.

In an embodiment, a surface energy of the graphene layer may be 0.4 mJ/m² to 115 mJ/m².

In an embodiment, at least a part of an upper surface and a lower surface of the base substrate may have fine curves.

Other aspects, features, and advantages other than those described above will become apparent from the following drawings, claims, and detailed descriptions of the disclosure

This general and specific aspect may be implemented using a system, method, computer program, or any combination of system, method, or computer program.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically illustrating a semiconductor package substrate according to an embodiment;

FIG. 2 is a cross-sectional view schematically illustrating a semiconductor package substrate according to an embodiment;

FIG. 3 is a cross-sectional view schematically illustrating a semiconductor package according to an embodiment;

FIGS. 4A and 4B are flowcharts illustrating a method of manufacturing a semiconductor package substrate according to an embodiment;

FIGS. 5 to 9 are cross-sectional views sequentially illustrating a method of manufacturing a semiconductor package substrate according to an embodiment;

FIG. 10 is a transmission electron microscope (TEM) image of a quad flat non-leaded package (QFN) substrate manufactured by a method of manufacturing a semiconductor package substrate according to an embodiment;

FIG. 11 shows images of QFN substrates manufactured by a method of manufacturing a semiconductor package substrate according to an embodiment and a comparative example;

FIG. 12 shows graphs for analyzing an anti-oxidation effect of the QFN substrates of FIG. 11;

FIGS. 13 and 14 show images of an evaluation result with respect to a QFN substrate manufactured by a manufacturing method according to an embodiment;

FIG. 15 is a cross-sectional view schematically illustrating a semiconductor package according to an embodiment; and

FIG. 16 is an enlarged view of part A of FIG. 15.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure may apply various transforms and have various embodiments, and particular embodiments are illustrated in the drawings and will be described in detail in the detailed description with reference to the illustrated drawings. The effects and features of the disclosure, and methods of achieving the effects and features, will become apparent with reference to the embodiments described in detail with reference to the drawings. However, the disclosure is not limited to the embodiments disclosed below, but may be implemented in various forms.

Hereinafter, embodiments of the disclosure will be described in detail with reference to the accompanying drawings, and the same or corresponding components will be denoted by the same reference numerals and redundant descriptions thereof will be omitted.

In the following embodiments, terms such as first, second, and the like are used for the purpose of distinguishing one component from another component, not for the limited meaning. In addition, the expression of the singular includes the expression of the plural, unless the context clearly indicates otherwise.

Meanwhile, terms such as include or have mean that the features or components described in the disclosure exist, and do not exclude in advance the possibility of adding one or more other features or components. In addition, when a part of a layer, region, component, etc. is above or on another part, it does not only include a case that the one part is directly on top of the other part, but also includes a case that another layer, region, component, etc. is disposed therebetween.

In the drawings, the sizes of components may be exaggerated or reduced for convenience of explanation. For example, the size and thickness of each component shown in the drawings are arbitrarily shown for convenience of explanation, and thus the disclosure is not necessarily limited to those illustrated.

The x-axis, y-axis, and z-axis are not limited to three axes on the orthogonal coordinate system, but may be interpreted in a broad sense including the same. For example, the x-axis, y-axis, and z-axis may be orthogonal to each other, but may also refer to different directions that are not orthogonal to each other.

When an embodiment is differently implemented, a specific process sequence may be performed differently from the order described. For example, two processes described as being performed in succession may be performed substantially simultaneously or may be performed in the opposite order to the order described.

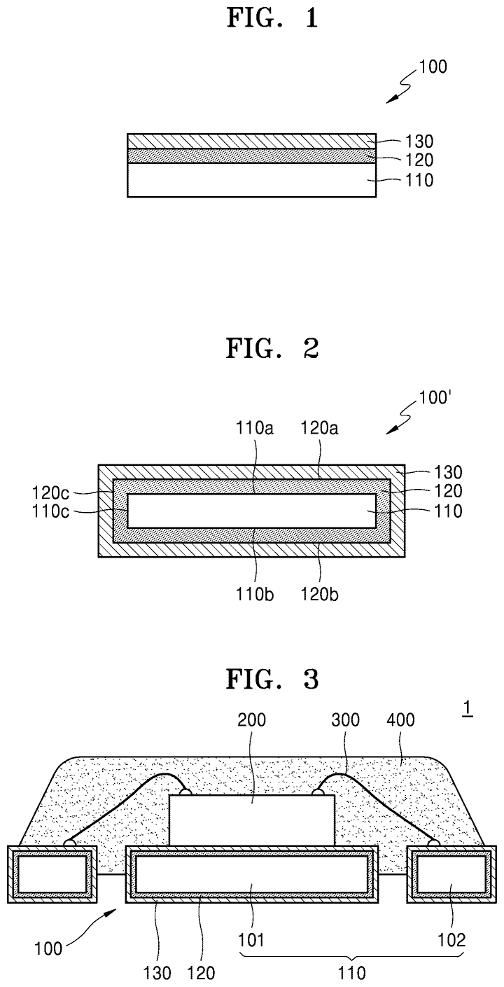

FIG. 1 is a cross-sectional view schematically illustrating a semiconductor package substrate according to an embodiment.

Referring to FIG. 1, a semiconductor package substrate 100 according to an embodiment may include a base substrate 110, a metal catalyst layer 120 disposed on the base substrate 110, and a graphene layer 130 disposed on the metal catalyst layer 120. The semiconductor package substrate 100 may transmit an electrical signal between a semiconductor and a main board and protect the semiconductor from an external impact.

The base substrate 110 may include a metal material including an electrically conductive material and may have a flat plate shape. The base substrate 110 may include copper (Cu) or a copper alloy material. For example, the copper alloy may include tin (Sn), zirconium (Zr), iron (Fe), zinc (Zn), phosphorus (P), etc. in addition to copper (Cu). In an embodiment, a thickness of the base substrate 110 may be about 100 μm to about 500 μm, for example, about 100 μm to about 200 μm. For example, the base substrate 110 may include a copper alloy including 97.4 % of copper (Cu), 2.4 % of iron, 0.13 % of zinc, and 0.03 % of others.

The metal catalyst layer 120 may be disposed on the base substrate 110. The metal catalyst layer 120 may be disposed to cover an upper surface of the base substrate 110. The metal catalyst layer 120 may facilitate synthesis of the graphene layer 130 to be used as an anti-oxidation film. When the base substrate 110 includes a copper alloy including a material other than copper, it may be difficult to synthesize a high-quality graphene layer. In the present embodiment, the high-quality graphene layer 130 may be synthesized by introducing the metal catalyst layer 120 having high purity.

For example, the metal catalyst layer 120 may include at least one of copper (Cu), nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt). The metal catalyst layer 120 may include a single layer including one of the materials and having high purity. For example, the metal catalyst layer 120 may include copper (Cu) having a purity of 99 % or more. Alternatively, the metal catalyst layer 120 may have a structure in which single layers each having a purity of 99 % or more are stacked. For example, the metal catalyst layer 120 may have various stack structures such as Cu/Ag, Cu/Au, Ni/Ag, Ni/Au, Pt/Cu, Rh/Ni, etc. The metal catalyst layer 120 may have a thickness of about 1 μm to about 10 μm.

The graphene layer 130 is disposed on the metal catalyst layer 120. The graphene layer 130 forms a two-dimensional (2D) planar sheet by connecting a plurality of carbon atoms to each other by covalent bonding, and the carbon atoms connected by covalent bonding form a six-membered ring as a basic repeating unit, but is also possible to further include a five-membered ring and/or a seven-membered ring. Thus, the graphene layer 130 may be configured as a single layer of carbon atoms (usually sp2 bonding) covalently bonded to each other. However, the disclosure is not limited thereto, and the graphene layer 130 may have a structure in which a plurality of single layers in a 2D planar sheet are stacked. The graphene layer 130 may have various structures, and such a structure may vary depending on the content of five-membered ring and/or seven-membered ring that may be included in the graphene layer 130.

A pore in a carbon lattice of the graphene layer 130 is formed to be smaller than the size of a molecule that causes metal surface oxidation such as a water molecule. Accordingly, the graphene layer 130 is formed on the base substrate 110, thereby preventing oxidation of the base substrate 110.

Meanwhile, the graphene layer 130 may be formed as a grain boundary region in which carbon atoms are continuously covalently bonded to have a constant crystal structure, and a grain boundary region in which carbon atoms are broken due to disrupted covalent bonding or include other impurities. This may mean that when a lot of grain boundary regions are formed in the graphene layer 130, an anti-oxidation effect may deteriorate.

In the present embodiment, the metal catalyst layer 120 is introduced between the base substrate 110 and the graphene layer 130, and thus the high-quality graphene layer 130 including more grain boundary regions may be formed, thereby maximizing an anti-oxidation effect.

Meanwhile, the graphene layer 130 according to the present embodiment may be formed through a low-temperature synthesis process. Heat treatment is required to synthesize the graphene layer 130, and the graphene layer 130 may be synthesized at a temperature of about 400° C. or less.

As described above, the base substrate 110 of the semiconductor package substrate 100 includes a thin film of a copper (Cu) material, and in the case of an alloy material of a copper substrate, high heat causes a reduction in substrate hardness due to a precipitation of an internal metal and dimension and shape deformation thereof, which may cause performance degradation and reliability problems of the semiconductor package substrate 100. Accordingly, the semiconductor package substrate 100 according to an embodiment synthesizes the graphene layer 130 for preventing oxidation at a low temperature of about 400° C. or less, thereby preventing the hardness reduction of the semiconductor package substrate 100.

In an embodiment, the semiconductor package substrate 100 may have a Vickers hardness Hv of 135 to 150, for example, 138 to 142. The semiconductor package substrate 100 serves as a support on which a semiconductor is mounted as a member that is a base for a semiconductor package, and thus requires a certain level of hardness. To stably mount the semiconductor, the Vickers hardness Hv of the semiconductor package substrate 100 may be 135 or more.

As described above, the graphene layer 130 according to an embodiment is synthesized at a temperature of 400° C. or less, and thus the Vickers hardness Hv of the semiconductor package substrate 100 may be maintained at 135 or more. As a comparative example, when a graphene layer is synthesized at more than 400° C. and 1000° C. or less, the hardness of a semiconductor package substrate is rapidly reduced, and the Vickers hardness (Hv) thereof is 20 to 35. The semiconductor package substrate having the hardness is difficult to stably mount a semiconductor, and thus the hardness of the semiconductor package substrate acts as an important factor, and low-temperature synthesis of the graphene layer 130 according to an embodiment is essentially required.

In an embodiment, the graphene layer 130 may have a thickness of about 0.3 nm to about 10 nm.

In an embodiment, the graphene layer 130 may have a surface energy of about 0.4 mJ/m² to about 115 mJ/m².

FIG. 2 is a cross-sectional view schematically illustrating a semiconductor package substrate according to an embodiment.

Referring to FIG. 2, a semiconductor package substrate 100′ according to an embodiment includes the base substrate 110, the metal catalyst layer 120 disposed on the base substrate 110, and the graphene layer 130 disposed on the metal catalyst layer 120.

The base substrate 110 may have a first surface 110a that is an upper surface, a second surface 110b that is a lower surface, and a third surface 110c that is a side surface connecting the upper surface to the lower surface. The metal catalyst layer 120 may be disposed to continuously cover the first surface 110a, the second surface 110b, and the third surface 110c of the base substrate 110.

In addition, the metal catalyst layer 120 may have a first surface 120a that is an upper surface, a second surface 120b that is a lower surface, and a third surface 120c that is a side surface connecting the upper surface to the lower surface. The graphene layer 130 may be disposed to continuously cover the first surface 120a, the second surface 120b, and the third surface 120c of the metal catalyst layer 120.

In other words, the metal catalyst layer 120 may be disposed to cover the entire surface of the base substrate 110, and the graphene layer 130 may be disposed to cover the entire surface of the metal catalyst layer 120. As described above, the graphene layer 130 that functions as an anti-oxidation film is disposed to cover the entire surface of the base substrate 110, which completely blocks a space where moisture or outside air may penetrate into the base substrate 110, thereby effectively preventing the base substrate 110 from oxidizing.

FIG. 3 is a cross-sectional view schematically illustrating a semiconductor package according to an embodiment.

Referring to FIG. 3, a semiconductor package 1 according to an embodiment may include the semiconductor package substrate 100, a semiconductor chip 200, bonding wires 300 connecting the semiconductor chip 200 to the semiconductor package substrate 100, and a mold resin 400.

The base substrate 110 includes a die pad portion 101 and a lead portion 102. The semiconductor chip 200 is attached to an upper surface of the semiconductor package substrate 100 corresponding to the die pad portion 101. A plurality of lead portions 102 may be formed, and the upper surface of the semiconductor package substrate 100 corresponding to the lead portion 102 may be connected to the semiconductor chip 200 by using the bonding wires 300. Although not shown, a lower surface of the semiconductor package substrate 100 corresponding to the lead portion 102 may be connected to an external device (not shown) through a solder ball (not shown). Accordingly, an electric signal output from the semiconductor chip 200 may be transmitted to the external device through the lead portion 102, and the electric signal input from the external device to the lead portion 102 may be transmitted to the semiconductor chip 200.

The base substrate 110 may have fine curves corresponding to at least a part of the surface, for example, an upper surface and a lower surface. The base substrate 110 having fine curves may mean that the base substrate 110 has a greater surface roughness in the corresponding portion. The adhesive force between a conductive organic adhesive layer 500 and the mold resin 400 to be described below may be further improved through fine curves of the base substrate 110. The base substrate 110 has fine bending, and thus the metal catalyst layer 120 and the graphene layer 130 to be described below may be formed along fine curves. Accordingly, fine curves are ultimately formed on the surface of the base substrate 110, and thus the surface of the semiconductor package substrate 100 may have fine curves.

The metal catalyst layer 120 and the graphene layer 130 may be disposed on the base substrate 110. FIG. 3 illustrates a structure in which the metal catalyst layer 120 and the graphene layer 130 are disposed to continuously cover the first surface 110a, the second surface 110b, and the third surface 110c of the base substrate 110, like the semiconductor package substrate 100′ described above with reference to FIG. 2.

In an embodiment, the graphene layer 130 may be disposed on the metal catalyst layer 120 to continuously surround upper, lower, and side surfaces of the die pad portion 101 and the lead portion 102 of the base substrate 110. When the graphene layer 130 is first formed before forming the die pad portion 101 and the lead portion 102, and the base substrate 110 is processed, moisture or outside air may penetrate into the side surfaces of the die pad portion 101 or the lead portion 102. Therefore, the semiconductor package substrate 100 according to an embodiment pre-processes the base substrate 110 and then forms the metal catalyst layer 120 and the graphene layer 130 on the base substrate 110 with the processed shape, and thus the graphene layer 130 may be disposed on not only the upper and lower surfaces but also the side surfaces of the die pad portion 101 and the lead portion 102. Accordingly, there is no space for moisture or outside air to penetrate into the base substrate 110, and thus the graphene layer 130 may sufficiently function as an anti-oxidation film.

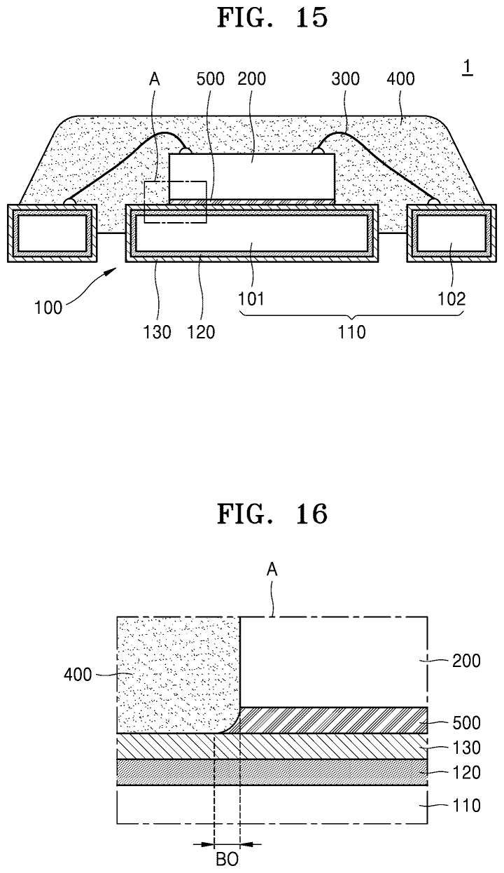

The semiconductor chip 200 may be mounted on an upper surface of the semiconductor package substrate 100. The semiconductor chip 200 may be disposed on the graphene layer 130 disposed on the die pad portion 101. An organic coating layer may be coated on the graphene layer 130 disposed on the die pad portion 101. The semiconductor chip 200 may be adhered to the graphene layer 130 of the die pad portion 101 through, for example, the conductive organic adhesive layer 500 (see FIG. 15) including epoxy. In this case, an organic coating layer (not shown) including an organic material may be coated on the graphene layer 130 of the die pad portion 101. The organic coating layer may be configured to prevent an epoxy bleed-out phenomenon.

The semiconductor chip 200 may be connected to the graphene layer 130 disposed in the lead portion 102 through the bonding wire 300. The bonding wire 300 may include a gold (Au) wire or a copper (Cu) wire. The bonding wire 300 needs to be firmly bonded to the semiconductor package substrate 100 so that a disconnection problem does not occur during subsequent signal transmission.

According to the present embodiment, the graphene layer 130 disposed on the lead portion 102 of the base substrate 110 has excellent bonding properties with the bonding wire 300, thereby improving product reliability. In the present embodiment, the wire pull strength of the bonding wire 300 coupled to the lead portion 102 may be 3.5 gf to 5 gf.

The mold resin 400 covers the semiconductor chip 200 and the bonding wire 300 mounted on the semiconductor package substrate 100 to encapsulate the upper surface of the semiconductor package substrate 100. The mold resin 400 may include a resin such as an epoxy mold compound.

Meanwhile, in an embodiment, as shown in FIG. 15, the conductive organic adhesive layer 500 may be further disposed between the semiconductor chip 200 and the semiconductor package substrate 100. The semiconductor chip 200 may be attached onto the semiconductor package substrate 100 through the conductive organic adhesive layer 500.

The conductive organic adhesive layer 500 may have a structure in which conductive fine particles are dispersed in a resin. The resin may include, for example, epoxy, polyimide, acrylic-based resin, silicone-based resin, phenol-based resin, bismaleimide triazine (BT) resin, etc. The conductive fine particles may include, for example, particles such as copper (Cu), nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), platinum (Pt), etc. For example, the conductive organic adhesive layer 500 may have a form in which silver (Ag) particles are dispersed in epoxy.

As described above, the semiconductor package substrate 100 includes the graphene layer 130, and the conductive organic adhesive layer 500 may be located on the graphene layer 130, and directly contact the graphene layer 130. In the disclosure, the surface energy of the graphene layer 130 is controlled to about 0.4 mJ/m² to about 115 mJ/m², the spreadability of the conductive organic adhesive layer 500 disposed on the graphene layer 130 may be easily controlled. Accordingly, the epoxy bleed-out phenomenon may be prevented.

Referring to FIG. 16, spreadability BO of the conductive organic adhesive layer 500 on the semiconductor package substrate 100 according to an embodiment may be about 2 mm or less. In this regard, a method of measuring ‘spreadability’ may be defined as expressing a numerical value of a range in which the conductive organic adhesive layer 500 spreads outward with respect to a region on which the conductive organic adhesive layer 500 is initially applied time.

In general, when the spreadability BO of the conductive organic adhesive layer 500 on the semiconductor package substrate 100 is 5 mm or more, this may be considered as an epoxy bleed out and evaluated as a defect. The semiconductor package substrate 100 according to an embodiment includes the graphene layer 130 on the surface thereof, and may easily control the spreadability BO of the conductive organic adhesive layer 500 disposed to be in contact with the graphene layer 130. For example, the spreadability BO of the conductive organic adhesive layer 500 in the semiconductor package 1 according to an embodiment may be 2 mm or less, specifically 0.01 mm or more and 2 mm or less. Experimentally, it was confirmed that the spreadability BO of the conductive organic adhesive layer 500 on the semiconductor package substrate 100 according to an embodiment is 0.05 mm or less.

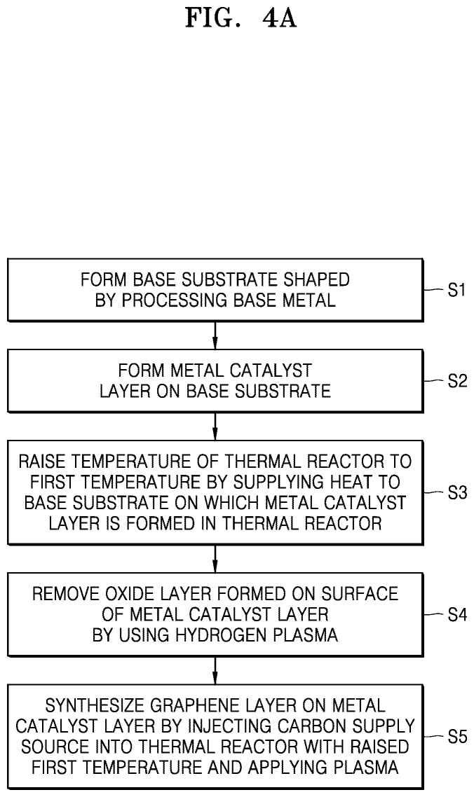

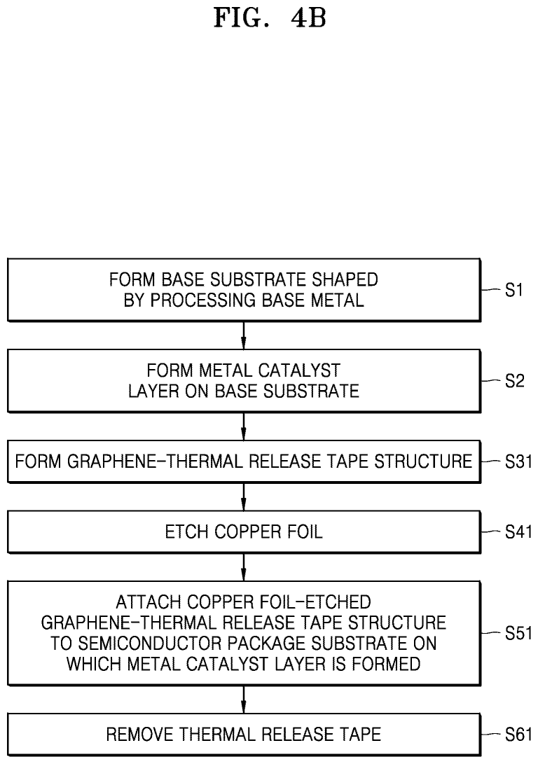

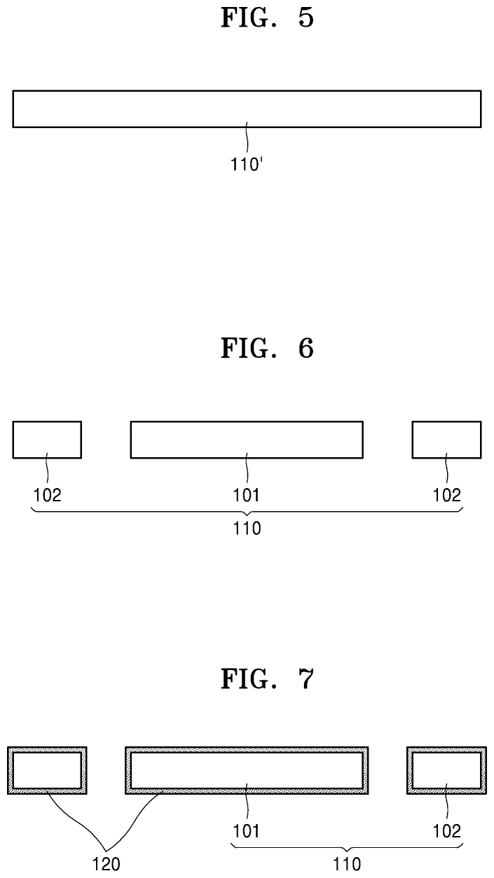

FIG. 4A is a flowchart illustrating a method of manufacturing a semiconductor package substrate according to an embodiment. FIGS. 5 to 9 are cross-sectional views sequentially illustrating a method of manufacturing a semiconductor package substrate according to an embodiment. FIG. 4B is a flowchart illustrating a method of manufacturing a semiconductor package substrate according to an embodiment.

Referring to FIG. 4A, the method of manufacturing the semiconductor package substrate according to an embodiment includes operation S1 of forming a base substrate shaped by processing a base metal, operation S2 of forming a metal catalyst layer on the base substrate, operation S3 of raising the temperature of a thermal reactor to a first temperature by supplying heat to the base substrate on which the metal catalyst layer is formed in the thermal reactor, operation S4 of removing an oxide layer formed on the surface of the metal catalyst layer by using hydrogen plasma, and operation S5 of synthesizing a graphene layer on the metal catalyst layer by injecting a carbon supply source into the thermal reactor with the raised first temperature and applying plasma.

Referring to FIG. 5, a base metal 110′including a metal material is prepared. The base metal 110′may include copper (Cu) or a copper alloy material. For example, the base metal 110′may be configured by using copper (Cu) as a main raw material and additionally including iron, zinc, and/or phosphorus. For example, the base metal 110′may include a copper alloy including 97.4 % of copper (Cu), 2.4 % of iron, 0.13 % of zinc, and 0.03 % of others. The base metal 110′ may be provided to have a thickness of about 100 μm to about 150 μm.

Next, referring to FIG. 6, the base substrate 110 including the die pad portion 101 and the lead portion 102 is formed by processing the base metal 110′ (S1).

To process the base substrate 110, a metal etching process may be performed after forming a photoresist pattern on the base substrate 110. The etching process may be a wet process. Alternatively, to process the base substrate 110, a process of forming a pattern by irradiating a laser beam may be performed. Through this process, the base substrate 110 including the die pad portion 101 and the lead portion 102 may be formed.

Next, referring to FIG. 7, the metal catalyst layer 120 is formed on the base substrate 110 (S2).

The metal catalyst layer 120 may be formed to cover at least a part of an upper surface, a lower surface, and side surfaces of the base substrate 110. That is, the metal catalyst layer 120 may be formed to cover at least a part of an upper surface, a lower surface, and side surfaces of each of the die pad portion 101 and the lead portion 102. In some embodiments, the metal catalyst layer 120 may be formed to continuously cover the upper surface, the lower surface, and the side surfaces of each of the die pad portion 101 and the lead portion 102.

The metal catalyst layer 120 may be at least one of copper (Cu), nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt). The metal catalyst layer 120 may be formed by various plating methods such as electroplating and non-electrolytic plating.

In an embodiment, the metal catalyst layer 120 may include one of the above materials and may include a single layer having a high purity. For example, the metal catalyst layer 120 may include copper (Cu) having a purity of 99 % or more. Alternatively, the metal catalyst layer 120 may have a structure in which single layers each having a purity of 99 % or more are stacked. For example, the metal catalyst layer 120 may have various stack structures such as Cu/Ag, Cu/Au, Ni/Ag, Ni/Au, Pt/Cu, Rh/Ni, etc. The metal catalyst layer 120 may have a thickness of 1 μm to 10 μm.

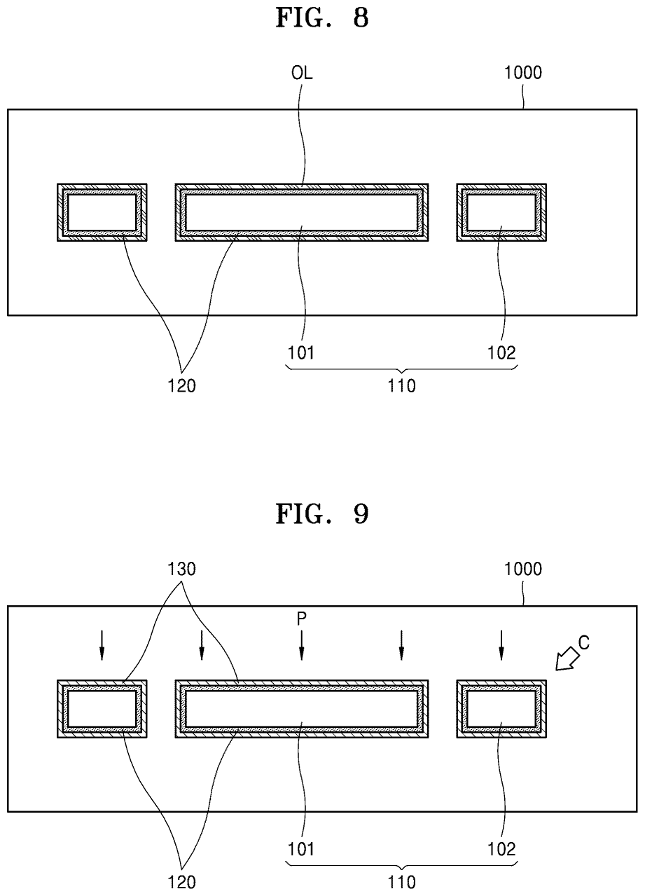

Thereafter, referring to FIG. 8, the temperature of a chamber 1000 which is the thermal reactor is raised to the first temperature by supplying heat to the base substrate 110 on which the metal catalyst layer 120 is formed in the chamber 1000 (S3). In addition, an oxide layer OL formed on the surface of the metal catalyst layer 120 may be removed using hydrogen plasma (S4) In this regard, the first temperature may be set to about 25° C. to about 400° C. The first temperature may be a temperature at which graphene is synthesized. As a heat source for supplying heat into the chamber 1000, for example, induction heating, radiant heat, laser, infrared, microwave, plasma, ultraviolet rays, surface plasmon heating, etc. may be used.

In an embodiment, operation S3 of raising the temperature of the chamber 1000 to the first temperature by supplying heat to the base substrate 110 on which the metal catalyst layer 120 is formed in the chamber 1000 and operation S4 of removing the oxide layer OL formed on the surface of the metal catalyst layer 120 using the hydrogen plasma may be performed simultaneously. That is, the oxide layer OL formed on the surface of the metal catalyst layer 120 may be removed by injecting the hydrogen plasma onto the surface of the metal catalyst layer 120 simultaneously while raising the inside of the chamber 1000 to the first temperature. As described above, the oxide layer OL formed on the surface of the metal catalyst layer 120 is removed, and thus graphene layer 130 may be more stably formed while increasing the adhesion with the graphene layer 130, which is a subsequent process. For example, the process of removing the oxide layer OL may be performed in a vacuum atmosphere.

Then, referring to FIG. 9, the graphene layer 130 may be synthesized on the metal catalyst layer 120 by injecting the carbon supply source C into the chamber 1000 with the raised first temperature and applying plasma P thereto (S5).

In an embodiment, a gas including carbon, that is, the carbon supply source C, may be injected into the chamber 1000 in the temperature raising operation. The carbon supply source C may be a compound having 12 or less carbon atoms, a compound having 4 or less carbon atoms, or a compound having 2 or less carbon atoms. As such an example, the carbon supply source may include one or more selected from the group consisting of methane, ethane, ethylene, ethanol, acetylene, propane, propylene, butane, butadiene, pentane, pentene, cyclopene, tadiene, hexane, cyclohexane, benzene, toluene, and coronene. Carbon may be absorbed into the metal catalyst layer 120 in the temperature raising operation.

In an embodiment, the vacuum pressure of the chamber 1000 in the temperature raising operation may be 10-3 Torr, and methane gas (CH4) may be used as the carbon supply source C. Methane gas may be injected at 30 sccm and raised to about 400° C. for 30 minutes.

For example, an operation of stabilizing a precursor in the process of injecting the carbon supply source C may be further included. The operation of stabilizing the precursor may include injecting only the carbon supply source C for about 1 minute before applying the plasma P to be described below.

Thereafter, an operation of synthesizing graphene is performed by injecting the carbon supply source C while maintaining the raised temperature of the chamber 1000 for a certain period of time.

In the process of forming the graphene layer 130, the internal temperature of the chamber 1000 is maintained at a low temperature of about 25° C. to about 400° C., and thus the plasma P is scanned together. For example, 20 sccm of acetylene gas and 100 sccm of hydrogen gas may be injected into the chamber 1000 with the raised temperature and maintained for 5 minutes, and then 200 W of plasma P may be applied thereto, and graphene may be synthesized for 1 hour. As described above, the plasma P is applied into the chamber 1000 at a low temperature, thereby stably forming the graphene layer 130 even at the low temperature of 400° C. or less.

FIG. 4B shows the method of manufacturing the semiconductor package substrate according to an embodiment, and may include operation S1 of forming a base substrate shaped by processing a base metal, operation S2 of forming a metal catalyst layer on the base substrate, operation S31 of forming a graphene-thermal release tape structure by attaching a thermal release tape to a copper foil on which a graphene layer is synthesized, operation S41 of etching the copper foil of the graphene-thermal release tape structure by using a copper foil etching solution, operation S51 of attaching the copper foil-etched graphene-thermal release tape structure to the semiconductor package substrate on which a metal catalyst layer is formed, and operation S61 of removing the thermal release tape.

Operation S1 of forming the base substrate shaped by processing the base metal, and operation S2 of forming the metal catalyst layer on the base substrate are the same as those described with reference to FIG. 4A.

Thereafter, operation S31 of forming the graphene-thermal release tape structure by attaching the thermal release tape to the copper foil on which the graphene layer is synthesized may be performed. Graphene used here may be, for example, single-layer or multilayer graphene grown directly on a surface of the copper foil through chemical vapor deposition (CVD). The thermal release tape may prevent structural damage to graphene during a transfer process and enable easy separation in subsequent processes.

Thereafter, operation S41 of etching the copper foil of the graphene-thermal release tape structure by using the copper foil etching solution is performed. More specifically, a process of removing the copper foil by immersing a graphene-thermal release tape film in the copper foil etching solution is performed. The etching solution used at this time may be, for example, an ammonium persulfate (NH₄)₂S₂O₈ or an iron (III) salt-based etching solution, and may include, for example, at least one of copper chloride, iron chloride, persulfate, ammonium persulfate, iron chloride, and gold chloride. This removes a metal layer (copper foil) in a lower portion of the graphene. As a result, the graphene remains supported by the thermal release tape.

Thereafter, operation S51 of attaching the copper foil-etched graphene-thermal release tape structure to the semiconductor package substrate on which the metal catalyst layer is formed is performed. More specifically, an operation of aligning a copper foil-removed graphene-thermal release tape on the semiconductor package substrate on which the metal catalyst is deposited, and attaching copper foil-removed graphene-thermal release tape by using a laminator is performed. At this time, a lamination process is performed under constant temperature and pressure, increases the adhesion between the graphene and the substrate, and simultaneously secures electrical contact between the graphene and the metal layer on the substrate surface.

Finally, operation S61 of removing the thermal release tape is performed. The graphene transfer process is completed by heating and removing the thermal release tape to which graphene is attached at a temperature of about 120° C. to about 180° C. The thermal release tape may be easily removed without damaging the graphene because its adhesion is weakened by heat.

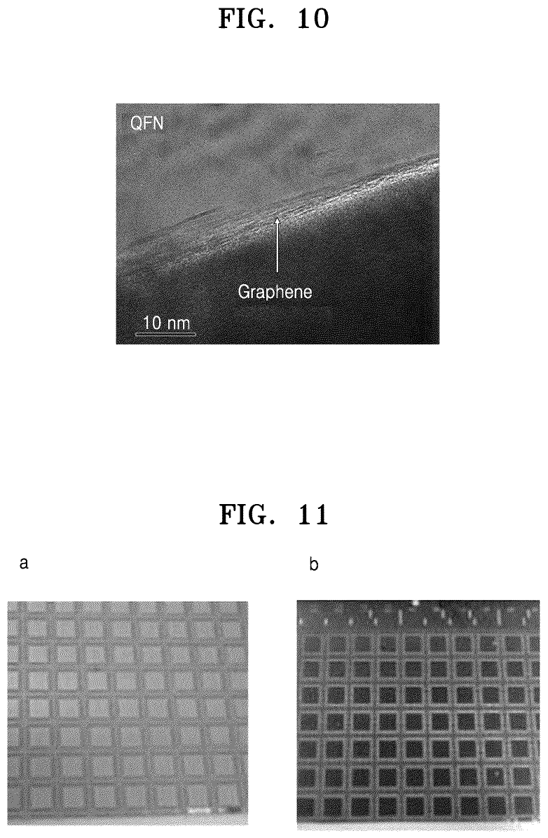

According to the manufacturing method of the disclosure, high-quality graphene may be transferred onto the substrate without damage, and electrical performance and thermal conductivity of the semiconductor package substrate may be improved by forming a stable interface between the graphene and the metal layer. In addition, the introduction of graphene enables improvement of EMI shielding and signal transmission characteristics, and thus the manufacturing method may be effectively applied to high-speed and high-integration semiconductor packaging FIG. 10 is a transmission electron microscope (TEM) image of a quad flat non-leaded package (QFN) substrate manufactured by a method of manufacturing a semiconductor package substrate according to an embodiment.

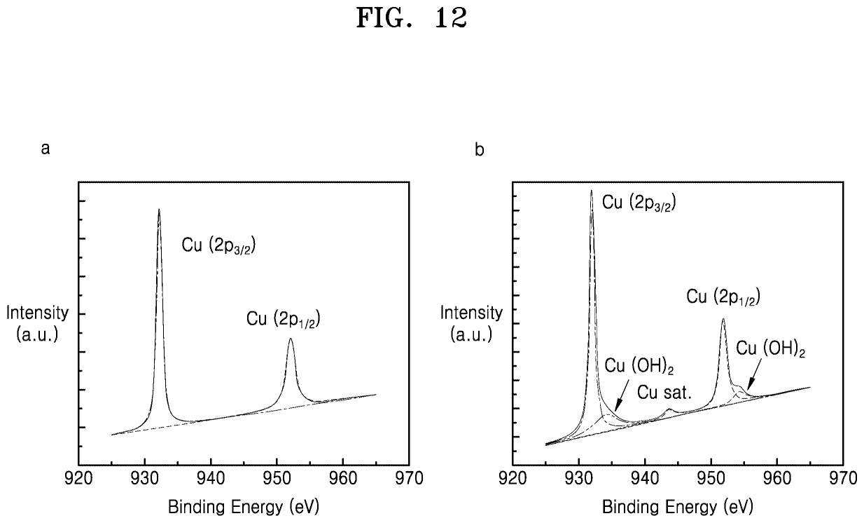

Referring to FIG. 10, in an embodiment, copper of 1 μm was deposited by using strike plating on the QFN substrate on which chip pads and wire leads were formed using patterning on a C194 copper alloy raw material of a thickness of 100 μm. The QFN substrate on which copper strike plating was formed was introduced into a plasma enhanced chemical vapor deposition (PECVD) chamber, and then the vacuum pressure was maintained at 10-3 Torr, and a copper oxide layer generated using hydrogen plasma was removed. A temperature raising operation was performed by heating the PECVD chamber to 400° C. for 30 minutes. 20 sccm of acetylene gas and 100 sccm of hydrogen gas were injected into the chamber with the raised temperature and maintained for 5 minutes, and then 200 W of plasma was applied and synthesis was performed for 1 hour. After a synthesis operation ends, natural cooling was performed. It may be confirmed from the TEM image of FIG. 11 that graphene synthesized through this process was stably synthesized on the QFN substrate.

FIG. 11 shows images of QFN substrates manufactured by a method of manufacturing a semiconductor package substrate according to an embodiment and a comparative example.

Referring to FIG. 11, the left image is the QFN substrate (a) manufactured by the method of manufacturing the semiconductor package substrate according to an embodiment, and a graphene layer is formed on the QFN substrate. The right image is the QFN substrate (b) on which no graphene layer is formed. As shown in FIG. 11, it may be seen that the QFN substrate (a) manufactured by the method of manufacturing the semiconductor package substrate according to an embodiment includes the graphene layer, and thus no oxide layer is formed. In addition, it may be seen that the QFN substrate (b) includes no graphene layer, and a red oxide layer is formed on the surface of QFN substrate (b).

FIG. 12 shows graphs for analyzing an anti-oxidation effect of the QFN substrates of FIG. 11.

Referring to FIG. 12, to verify whether a semiconductor substrate to which a graphene layer is applied is anti-oxidized, an oxidation acceleration evaluation was performed. The substrate (a) on which the graphene layer manufactured by the manufacturing method according to an embodiment was synthesized was injected into an environmental test analyzer chamber and subjected to oxidation acceleration treatment at a temperature of 85° C. and a humidity of 85 % for 5 hours. At this time, as a comparative example, the substrate (b) into which no graphene was introduced was simultaneously treated. After the oxidation acceleration evaluation, the substrate (a) on which the graphene layer was formed was not discolored, and the substrate (b) on which no graphene was formed was discolored.

As a result of analysis by X-ray photoelectron spectroscopy to analyze the anti-oxidation effect, the QFN substrate (b) on which no graphene was formed has a peak detected near 945 eV, which indicates that Cu2O was formed, whereas the QFN substrate (a) on which the graphene layer was formed has no oxidation peak detected, which indicates that no oxide layer was formed.

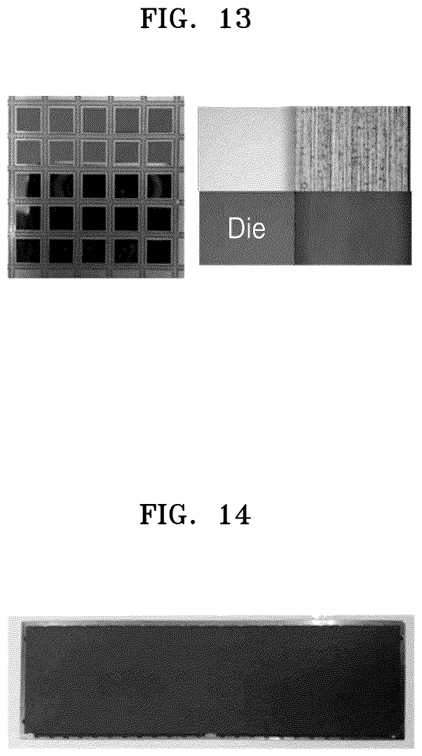

FIGS. 13 and 14 show images of an evaluation result with respect to a QFN substrate manufactured by a manufacturing method according to an embodiment.

Referring to FIG. 13, the adhesion between the QFN substrate on which a graphene layer is formed and a die attachment film was confirmed through die attachment of a semiconductor package substrate on which the graphene layer was formed. In an embodiment, a mirror wafer of a certain size (e.g., 6×6) and thickness (e.g., 200 μm) was attached to the substrate at 120 degrees of DA, and curing was performed at 130 degrees for 1 hour. As a result, as shown in the image of FIG. 13, it may be confirmed that a die is well adhered to the semiconductor package substrate on which the graphene layer is formed.

In addition, referring to FIG. 14, it was confirmed that a mold is well formed on the semiconductor package substrate to which the die was adhered using an EMC molding evaluation.

According to an embodiment as described above, a composition for a semiconductor package substrate with improved bending of the semiconductor package substrate during manufacturing and the semiconductor package substrate including the same may be implemented. The scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A semiconductor package substrate comprising:
a base substrate comprising a conductive material, a die pad portion, and a lead portion;
a metal catalyst layer disposed on the base substrate; and
a graphene layer disposed on the metal catalyst layer,
wherein the semiconductor package substrate has a Vickers hardness of 135 to 150.

2. The semiconductor package substrate of claim 1, wherein the metal catalyst layer includes at least one of copper (Cu), nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt).

3. The semiconductor package substrate of claim 1, wherein the base substrate includes copper (Cu).

4. The semiconductor package substrate of claim 1, wherein the graphene layer is directly disposed on the metal catalyst layer.

5. The semiconductor package substrate of claim 4, wherein no oxide layer is disposed between the graphene layer and the metal catalyst layer.

6. The semiconductor package substrate of claim 1, wherein the metal catalyst layer is disposed on at least one of a first surface of the base substrate, a second surface located on the opposite side of the first surface, and a third surface connecting the first surface to the second surface.

7. The semiconductor package substrate of claim 6, wherein the graphene layer is disposed on at least one of a first surface of the metal catalyst layer, a second surface located on the opposite side of the first surface, and a third surface connecting the first surface to the second surface.

8. The semiconductor package substrate of claim 1, wherein a surface energy of the graphene layer is 0.4 mJ/m² to 115 mJ/m².

9. The semiconductor package substrate of claim 1, wherein at least a part of an upper surface and a lower surface of the base substrate has fine curves.

10. A semiconductor package comprising:
the semiconductor package substrate according to claim 1;
a semiconductor chip disposed on the die pad portion; and
a bonding wire connecting the semiconductor chip to the lead portion, wherein the bonding wire is in direct contact with the graphene layer.
